(19) United States
(12) Patent Application Publication
(10) Pub. No.: US 2018/0375027 A1
(43) Pub. Date: Dec. 27, 2018

(54) MASK PLATE AND MANUFACTURING METHOD THEREOF, AND MANUFACTURING METHOD OF ORGANIC LIGHT EMITTING DIODE DISPLAY

(71) Applicant: BOE TECHNOLOGY GROUP CO., LTD, Beijing (CN)

(72) Inventors: Can ZHANG, Beijing (CN); Xiaochuan CHEN, Beijing (CN)

(21) Appl. No.: 15/744,359

(22) PCT Filed: Jun. 26, 2017
(86) PCT No.: PCT/CN2017/089949

§ 371 Date: Jan. 12, 2018

(30) Foreign Application Priority Data
Nov. 11, 2016 (CN) 201610994601.8

(51) Int. Cl. H01L 51/00; H01L 51/56; C23C 14/04

(52) U.S. Cl. CPC H01L 51/0011; H01L 27/3244; C23C 14/042; H01L 51/56

(57) ABSTRACT

A mask plate includes a mask substrate and a plurality of openings passing through the mask substrate, and a material of the mask plate is monocrystalline silicon. A manufacturing method of a mask and a manufacturing method of an organic light emitting diode display are also provided.

### TECHNICAL FIELD

At least one embodiment of the present disclosure relates to a mask plate and a manufacturing method thereof, and a manufacturing method of an organic light emitting diode display.

### BACKGROUND

Silicon-based (Active-matrix organic light emitting diode, AMOLED) micro displays have an extensive market application space, and are especially suitable for use in a helmet display, a stereoscopic display glass and a glass-type display etc. . . . The micro displays are capable of obtaining accurate image information in anytime and anywhere when the micro displays are combined with systems such as a mobile communication network and a satellite positioning, which has very important military value in military applications such as national defense, aviation, spaceflight and even individual combat. The silicon-based AMOLED micro displays are capable of providing high-quality video display for mobile information products such as a portable computer, a wireless internet browser, a portable DVD, a play station and a wearable computer and so on. It can be noted that the silicon-based AMOLED micro-displays provide an excellent near-eye application (such as helmet display) for both civilian consumption and industrial applications as well as military applications.

### SUMMARY

At least one embodiment of the present disclosure provides a mask plate and a manufacturing method thereof, and a manufacturing method of an organic light emitting diode display. The mask plate with a material of monocrystalline silicon can be configured to form at least one layer of a micro organic light emitting diode, and form micro organic light emitting diodes emitting light of different colors, so as to achieve full-color display.

At least one embodiment of the present disclosure provides a mask plate, which includes a mask substrate and a plurality of openings passing through the mask substrate, a material of the mask plate is monocrystalline silicon.

For example, in the mask plate provided by an embodiment of the present disclosure, the mask substrate has a thickness of 100 microns to 300 microns.

For example, in the mask plate provided by an embodiment of the present disclosure, the plurality of openings are arranged in a matrix, the matrix includes a plurality of rows and a plurality of columns, at least one of a lengths in a row direction and in a column direction of each of the openings is less than or equal to 10 microns.

For example, in the mask plate provided by an embodiment of the present disclosure, the plurality of openings extend in a first direction, and are arranged in a second direction which is perpendicular to the first direction, a length of each of the openings in the second direction is less than or equal to 10 microns.

For example, the mask plate provided by an embodiment of the present disclosure further includes an alignment hole, and the alignment hole is disposed in the mask substrate, and configured to be aligned with an alignment mark of a display substrate.

For example, in the mask plate provided by an embodiment of the present disclosure, the mask plate is configured to form at least one layer of a micro organic light emitting diode, an area of the micro organic light emitting diode is greater than or equal to 1 square micron and less than or equal to 300 square microns.

At least one embodiment of the present disclosure further provides a manufacturing method of a mask plate, which includes forming a plurality of openings in a mask substrate with the openings passing through the mask substrate; a material of the mask plate is monocrystalline silicon.

For example, in the manufacturing method of the mask plate provided by an embodiment of the present disclosure, before forming the plurality of openings, the manufacturing method further includes thinning a mask material to form the mask substrate, the mask substrate has a thickness of 100 microns to 300 microns.

At least one embodiment of the present disclosure further provides a manufacturing method of an organic light emitting diode display, which includes forming a plurality of micro organic light emitting diodes, at least one layer of the micro organic light emitting diodes is formed by using any mask plate provided by at least one embodiment of the present disclosure.

For example, in the manufacturing method of the organic light emitting diode display provided by an embodiment of the present disclosure, an area of each of the micro organic light emitting diodes is greater than or equal to 1 square micron and less than or equal to 300 square microns.

For example, in the manufacturing method of the organic light emitting diode display provided by an embodiment of the present disclosure, the at least one layer of the micro organic light emitting diodes includes at least one of a hole injection layer, a hole transport layer, a hole blocking layer, a light emitting layer, an electron injection layer, an electron transport layer, an electron blocking layer and an electrode layer.

For example, in the manufacturing method of the organic light emitting diode display provided by an embodiment of the present disclosure, the plurality of micro organic light emitting diodes include micro organic light emitting diodes emitting light of different colors.

### BRIEF DESCRIPTION OF THE DRAWINGS

In order to clearly illustrate the technical solution of embodiments of the present disclosure, the drawings of the embodiments will be briefly described in the following, it is obvious that the drawings in the description are only related to some embodiments of the present disclosure and not limited to the present disclosure.

FIG. 1 is a view of a mask plate provided by an embodiment of the present disclosure;

FIG. 2 is another mask plate provided by an embodiment of the present disclosure;

FIG. 3 is a view of an alignment of a mask plate and a display substrate provided by an embodiment of the present disclosure;

FIG. 4 is a view of a silicon-based AMOLED (Active-matrix organic light emitting diode) display substrate provided by an embodiment of the present disclosure;

FIG. 5 is a view of another silicon-based AMOLED display substrate provided by an embodiment of the present disclosure;

FIG. 6 is a view of a micro OLED (organic light emitting diode) device emitting light of one color which is formed on a display substrate provided by an embodiment of the present disclosure;

FIG. 7 is a view of a micro OLED device emitting light of one color which is formed on a display substrate provided by an embodiment of the present disclosure;

FIG. 8 is a view of a pixel structure in an OLED display substrate provided by an embodiment of the present disclosure.

### REFERENCE SIGNS

10—mask substrate; 101—opening; 102—alignment hole; 20—display substrate; 200—base substrate; 2001—first color sub-pixel; 2002—second color sub-pixel; 2003—third color sub-pixel; 201—alignment mark; 202—reflective layer; 203—buffer layer; 204—active layer; 2041—source electrode contact region; 2042—channel region; 2043—drain electrode contact region; 205—pixel electrode; 206—gate insulating layer; 207—source electrode; 208—drain electrode; 209—gate electrode; 210—passivation layer; 211—pixel definition layer; 212—hole transport layer; 213—organic light emitting layer; 214—electron transport layer; 215—electrode layer; 2345—micro organic light emitting diode; 30—alignment system.

### DETAILED DESCRIPTION

In order to manufacture objects, technical details and advantages of the embodiments of the present disclosure apparently, the technical solutions of the embodiments will be described in a clearly and fully understandable way in connection with the drawings related to the embodiments of the present disclosure. It is obvious that the described embodiments are just a part but not all of the embodiments of the present disclosure. Based on the described embodiments herein, a person having ordinary skill in the art may obtain other embodiment(s), without any inventive work, which should be within the scope of the disclosure.

Unless otherwise defined, the technical terms or scientific terms used herein have the same meanings as commonly understood by a person having ordinary skill in the art to which the present disclosure belongs. The terms “first,” “second,” etc., which are used in the description and the claims of the present disclosure, are not intended to indicate any sequence, amount or importance, but distinguish various components. The terms “include,” “comprise,” etc., are intended to specify that the elements or the objects stated before these terms encompass the elements or the objects and equivalents thereof listed after these terms, but do not preclude the other elements or objects. The terms “connect” or “connection” and the like are not limited to physical or mechanical connections but may include electrical connections, whether direct or indirect. “On”, “under”, “right”, “left” and the like are only used to indicate relative position relationship, and when the position of the object which is described is changed, the relative position relationship may be changed accordingly.

A usual colorized silicon-based AMOLED is manufactured by using a white organic light emitting diode in conjunction with a color filter (white organic light emitting diode+color filter, WOLED+CF). Because the color filter (CF) has a lower transmittance of about 30˜40%, a display with the color filter may lose most of the light efficiency and increase the power consumption. A conventional method of directly depositing sub-pixels by using a fine metal mask (FMM) technology cannot be applied to a micro organic light emitting diode (micro-OLED). For example, the sub-pixels include red, green and blue (RGB) sub-pixels. Because the size of the sub-pixels in the micro-OLED is smaller, usually a few microns, a usual FMM technology cannot meet the precision requirement of the micro-OLED, and the FMM may offset upon being stretched, a new mask technology is required for a full-color technology of the micro-OLED.

At least one embodiment of the present disclosure provides a mask plate, which includes a mask substrate and a plurality of openings passing through the mask substrate, a material of the mask plate is monocrystalline silicon. The mask plate with a material of monocrystalline silicon has sufficient rigidity and strength, so as to be configured to manufacture at least one layer of a micro organic light emitting diode. The mask plate can be configured to manufacture micro organic light emitting diodes emitting light of different colors, so as to achieve full-color display.

At least one embodiment of the present disclosure provides a manufacturing method of a mask plate, which includes: forming a plurality of openings in a mask substrate with the openings passing through the mask substrate, a material of the mask plate being monocrystalline silicon. The mask plate using monocrystalline silicon has sufficient rigidity and strength, so as to be configured to manufacture at least one layer of a micro organic light emitting diode.

At least one embodiment of the present disclosure further provides a manufacturing method of an organic light emitting diode display, which includes forming a plurality of micro organic light emitting diodes, at least one layer of the micro organic light emitting diodes is formed by using any mask plate provided by at least one embodiment of the present disclosure. Therefore, a full-color organic light emitting diode display may be manufactured by using any mask plate described in embodiments of the present disclosure. A color filter layer does not need to be manufactured in the organic light emitting diode, so as to improve light efficiency and reduce power consumption of the micro organic light emitting diode.

The following is further illustrated by several embodiments.

### First Embodiment

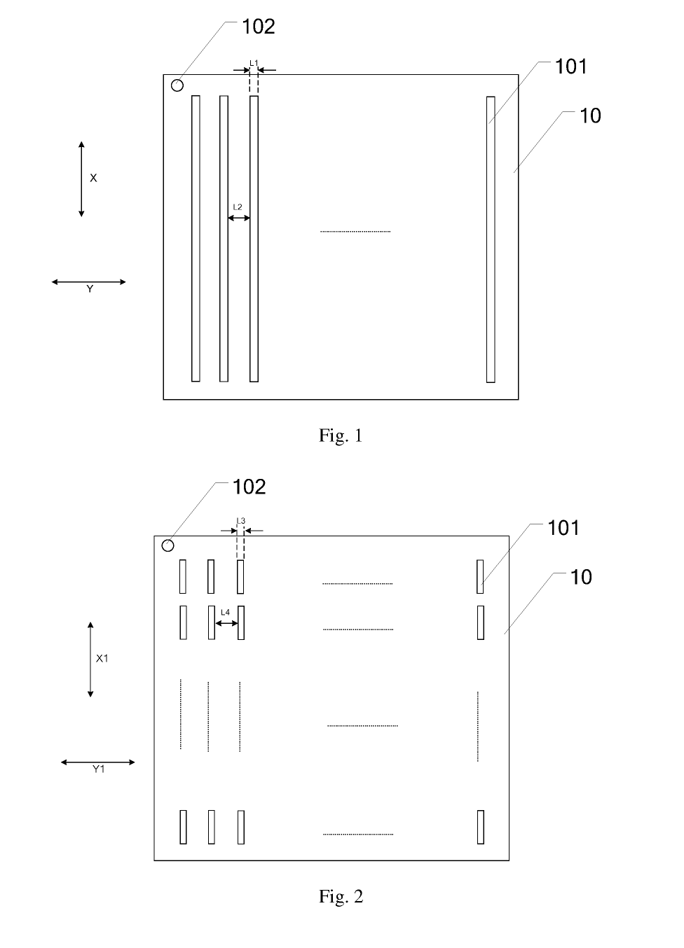

As illustrated in FIG. 1, the present embodiment provides a mask plate, which includes a mask substrate 10 and a plurality of openings 101 passing through the mask substrate 10, a material of the mask plate is monocrystalline silicon. Therefore, the mask plate may be used to form at least one layer of a micro organic light emitting diode. The monocrystalline silicon has a smaller linear thermal expansion coefficient of 2.5×10⁻⁶/° C., the mask plate with the monocrystalline silicon has sufficient rigidity and strength, and does not require to be stretched, and is configured to form at least one layer of the micro organic light emitting diode. The openings are easy to be manufactured on the monocrystalline silicon with a usual process. The mask plate provided by the present disclosure may manufacture micro organic light emitting diodes emitting light of different colors, so as to achieve full-color display of a micro display. For example, a display which has a size less than 1 inch is called a micro display.

For example, an area of the micro organic light emitting diode is greater than or equal to 1 square micron and less than or equal to 300 square microns. Any mask plate provided by the present embodiment may be used for manufacturing the micro organic light emitting diode. For example, the area of the micro organic light emitting diode is greater than or equal to 1 square micron and less than or equal to 150 square microns. For example, the area of the micro organic light emitting diode is greater than or equal to 1 square micron and less than or equal to 110 square microns. Even if the area of the micro organic light emitting diode is several square microns, the mask plate provided by the present embodiment may also be used to manufacture the micro organic light emitting diode. The size of the openings of the mask plate may be adjusted according to the size of sub-pixels in a display substrate to be manufactured.

For example, the mask substrate may have a thickness of 100 microns to 300 microns. The mask plate manufactured from the mask substrate within this thickness range may have sufficient rigidity and strength, and the mask plate is benefit to a manufacture of a film. If the mask plate is too thin, it will be fragile. If the mask plate is too thick, there may be a shadow effect in a pattern evaporated by the mask plate. For example, the shadow effect means that the evaporation pattern is larger than a designed pattern. Furthermore, the mask substrate 10 may have a thickness of 200 microns to 300 microns. Furthermore, the mask substrate 10 may have a thickness of 250 microns to 300 microns. The mask substrate 10 within the above thickness range enables the mask plate to have better performance, and the mask plate is easy to be manufactured.

FIG. 1 is a view of a mask plate provided by an embodiment of the present disclosure, as illustrated in FIG. 1, in the first example, the plurality of openings 101 extend in a first direction X, and are arranged in a second direction Y which is perpendicular to the first direction X. For example, each of the openings 101 corresponds to a row of sub-pixels, or, each of the openings corresponds to a column of the sub-pixels, but not limited thereto. For example, a length L1 of each of the openings 101 in the second direction Y may correspond to a length of a sub-pixel in the second direction Y. For example, the length L1 of each of the openings 101 in the second direction Y may be less than or equal to 10 microns. Therefore, the mask plate may be configured to form at least one layer of the micro organic light emitting diode. For example, the length L1 of each of the openings 101 in the second direction Y may be less than or equal to 7 microns. For example, the length L1 of each of the openings 101 in the second direction Y may be less than or equal to 4 microns. For example, the length L1 of each of the openings 101 in the second direction Y is greater than or equal to 2 microns and less than or equal to 4 microns. For example, a distance between two adjacent openings, that is a distance L2 between the two adjacent openings in the second direction Y, may correspond to a length of at least one sub-pixel in the second direction Y. For example, the distance between the two adjacent openings may correspond to a length of two or third sub-pixels in the second direction Y. For example, the distance between the adjacent two openings may be greater than or equal to 2 microns and less than or equal to 30 microns. For example, the distance between the adjacent two openings may be greater than or equal to 2 microns and less than or equal to 20 microns. For example, the distance between the adjacent two openings may be greater than or equal to 2 microns and less than or equal to 8 microns.

FIG. 2 is a view of another mask plate provided by the present embodiment, as illustrated in FIG. 2, in the second example, the plurality of openings 101 are arranged in a matrix, the matrix includes a plurality of rows and a plurality of columns. For example, each of the openings corresponds to one sub-pixel, but not limited thereto. For example, at least one of a length in a row direction Y1 and a length in a column direction X1 of each of the openings 101 may be less than or equal to 10 microns. Therefore, the mask plate may be configured to form at least one layer of the micro organic light emitting diode. For example, at least one of the length in the row direction Y1 and the length in the column direction X1 of each of the openings 101 is less than or equal to 7 microns. For example, at least one of the length in the row direction Y1 and the length in the column direction X1 of each of the openings 101 is less than or equal to 4 microns. For example, at least one of the length in the row direction Y1 and the length in the column direction X1 of each of the openings 101 is greater than or equal to 2 microns and less than or equal to 4 microns. For example, the length L3 of each of the openings 101 in the row direction Y1 is within the numerical ranges as mentioned above. For example, a distance between two adjacent openings, that is a distance L4 between the two adjacent openings in the row direction Y1 may correspond to a length of at least one sub-pixel in the row direction Y1. For example, the distance between the two adjacent openings may correspond to a length of two or third sub-pixels in the row direction Y1. For example, the distance between the adjacent two openings may be greater than or equal to 2 microns and less than or equal to 30 microns. For example, the distance between the adjacent two openings may be greater than or equal to 2 microns and less than or equal to 20 microns. For example, the distance between the adjacent two openings in the row direction Y1 may be greater than or equal to 2 microns and less than or equal to 8 microns.

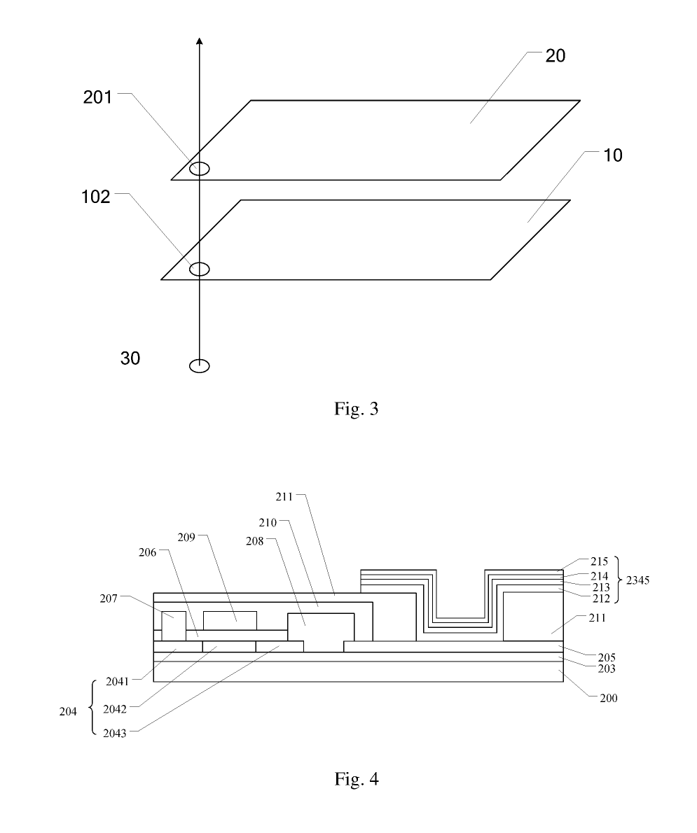

For example, as illustrated in FIG. 1 and FIG. 2, the mask plate further includes an alignment hole 102. FIG. 3 is a view of an alignment of a mask plate and a display substrate provided by the present embodiment, as illustrated in FIG. 3 (FIG. 3 does not illustrate the plurality of openings 101 passing through the mask substrate 10), the alignment hole 102 is disposed on the mask substrate 10, and configured to be aligned with an alignment mark 201 of a display substrate 20. Through the alignment hole 102 and the alignment mark 201, an alignment system 30 may be configured to align the mask plate with the display substrate 20. A plurality of alignment marks 201 may be disposed on the display substrate 20; therefore, in a case that manufacturing micro organic light emitting diodes emitting monochromatic light of different colors, the mask plate is translated to be aligned.

### Second Embodiment

The present embodiment provides a manufacturing method of a mask plate, which includes forming a plurality of openings 101 in a mask substrate 10 with the openings passing through the mask substrate 10, a material of the mask plate being monocrystalline silicon.

Any mask plate as mentioned in the first embodiment can be formed by using the manufacturing method provided by the present embodiment. For example, the formed mask plate may be illustrated in FIG. 1 and FIG. 2.

For example, before forming the plurality of openings 101, the manufacturing method further includes thinning a mask material to form the mask substrate 10, the mask substrate 10 has a thickness of 100 microns to 300 microns. For example, the mask material may be thinned by grinding.

For example, the mask substrate 10 may be etched out of a desired pattern by dry etching and wet etching. For example, the dry etching includes plasma etching. For example, in a case that using the dry etching method, the plurality of openings 101 which pass through the mask substrate 10 may be formed in the mask substrate 10 with monocrystalline silicon by plasma etching. For example, in a case that using the wet etching method, a silicon oxide layer may be formed on the mask substrate 10, and the silicon oxide layer may be patterned, and then the mask substrate is wet etched using the patterned silicon oxide as a mask. Therefore, the plurality of openings 101 which pass through the mask substrate 10 are formed in the mask substrate 10 of monocrystalline silicon. It should be noted that, the method of forming the plurality of openings 101 passing through the mask substrate 10 in the mask substrate 10 of monocrystalline silicon is not limited to the case listed above.

For example, the mask substrate may be thinned by chemical mechanical polishing (CMP).

For example, the manufacturing method may further includes forming an alignment hole 102 in the mask substrate 10, the alignment hole 102 is configured to be aligned with an alignment mark 201 of a display substrate 20. Because the mask substrate 10 is opaque, the dry etching method or the wet etching method may be used to etch the mask substrate 10 to form the alignment hole. The manufacturing method of the alignment hole may refer to the manufacturing method of the plurality of openings 101 passing through the mask substrate 10. The alignment hole 102 may be illustrated in FIG. 1 to FIG. 3.

In an example, the plurality of openings 101 arranged in a matrix are formed in the mask substrate 10, the matrix includes a plurality of rows and a plurality of columns, at least one of a length in a row direction and a length in a column direction of each of the openings 101 is less than or equal to 10 microns.

In another example, the plurality of openings 101 extending along a first direction and arranged in a second direction which is perpendicular to the first direction are formed on the mask substrate 10, at least one of lengths of each of the openings 101 along the second direction is less than or equal to 10 microns.

The mask plate provided by the two examples as mentioned above may be described by referring to the first embodiment, so as to form the mask plate corresponds to the examples, related details are not repeated thereto.

### Third Embodiment

The present embodiment provides a manufacturing method of an organic light emitting diode display, which includes forming a plurality of micro organic light emitting diodes, at least one layer of the micro organic light emitting diodes is formed by using any mask plate provided by the first embodiment.

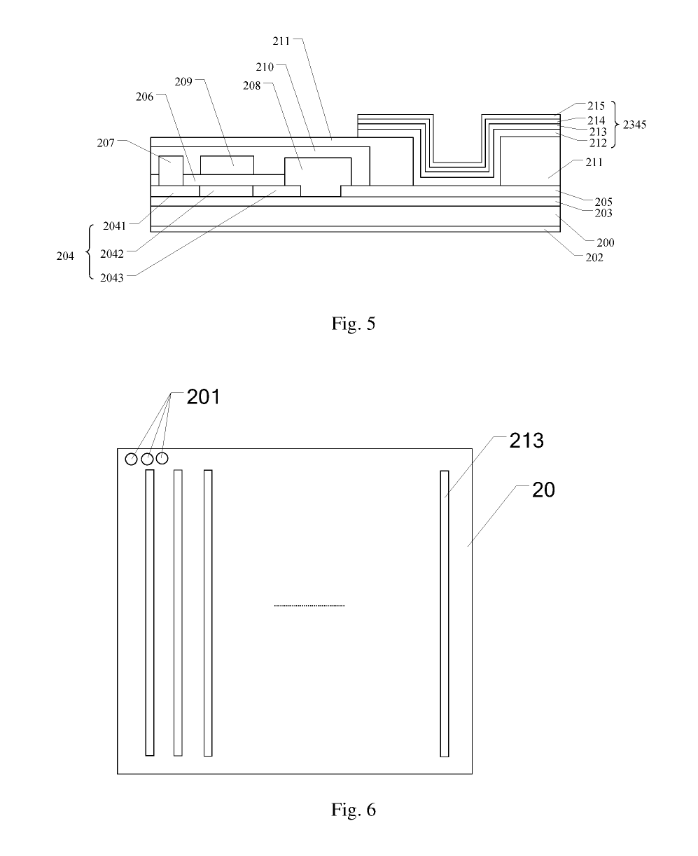

FIG. 4 illustrates a silicon-based active-matrix organic light emitting diode (AMOLED) display substrate, which includes a base substrate 200, a buffer layer 203 disposed on the base substrate 200, an active layer 204 disposed on the buffer layer 203, the active layer 204 includes a channel region 2042, a source electrode contact region 2041 and a drain electrode contact region 2043. The active layer 204 is provided with a gate insulating layer 206 thereon, the gate insulating layer 206 is provided with a gate electrode 209 thereon. A source electrode 207 and a drain electrode 208 are respectively connected to the source electrode contact region 2041 and the drain electrode contact region 2043 through via holes. A pixel electrode 205 is disposed on the buffer layer 203, the pixel electrode 205 is electrically connected with the drain electrode 208. A passivation layer 210 is disposed on the gate electrode 209, the source electrode 207 and the drain electrode 208. A pixel definition layer 211 is formed on the above mentioned structure, and the pixel definition layer 211 is configured to define sub-pixel regions, so that a micro OLED device 2345 is formed on the pixel definition layer 211. The micro OLED device 2345 is in connection with the pixel electrode 205. The micro OLED device 2345 illustrated in FIG. 4 includes a hole transport layer 212, an organic light emitting layer 213, an electron transport layer 214 and an electrode layer 215. The electrode layer illustrated in FIG. 4 is a cathode layer. However, alternatively, the electrode layer 215 may also be an anode layer, and the lamination sequence of the micro OLED device needs to be adjusted accordingly. FIG. 5 illustrates a view of another silicon-based AMOLED display substrate, a difference from FIG. 4 is a reflective layer 202 disposed on another side of the base substrate 200 which is illustrated in FIG. 5 for reflecting the light emitted by the OLED device. For example, the reflective layer 202 may be made of metal.

For example, a material of the source electrode 207 and the drain electrode 208 includes metal. For example, the channel region 2042 uses amorphous silicon (α-Si), the source electrode contact region 2041 and the drain electrode contact region 2043 may form n⁺ α-Si to form an ohmic contact. For example, the pixel electrode 205 may have a material of metal or conductive metal oxide. For example, the material may be silver, indium tin oxide, and so on. It should be noted that, the material of the active layer is not limited to the materials listed above, and other suitable materials may be used, the present embodiment is not limited thereto. For example, the material of each structure as mentioned above may refer to the usual design, but is not limited thereto.

For example, at least one layer of the micro OLED device 2345 may be formed by the mask plate provided by the first embodiment. Each layer of the micro OLED device 2345 may be formed by the mask plate provided by the first embodiment. It should be noted that, each layer structure laminated in the micro OLED device 2345 is not limited to a case illustrated in FIG. 5. For example, the micro OLED device 2345 may include a hole injection layer, a hole transport layer, a light emitting layer, an electron transport layer, an electron injection layer, and an electrode layer which are laminated. Or, the micro OLED device 2345 may include an electron injection layer, an electron transport layer, a light emitting layer, a hole transport layer, a hole injection layer and an anode layer which are laminated. At least one layer may be added or subtracted according the need. For example, the micro OLED device may further includes a hole blocking layer or an electrode blocking layer, the hole blocking layer may be disposed between the electron transport layer and the light emitting layer, the electron blocking layer may be disposed between the hole transport layer and the light emitting layer, but is not limited thereto. For example, the hole blocking layer or the electron blocking layer may be made of organic material.

For example, the hole injection layer may be made of triphenylamine compounds or a p-type doped organic layer or a polymer, for example tris-[4-(5-phenyl-2-thienyl)benzene]amine, 4,4′,4″-tris[2-naphthyl(phenyl)amino]triphenylamine (2-TNATA) or 4,4′,4″-tris-(3-methylphenylanilino)triphenylamine (m-MTDATA), phthalocyanine copper (CuPc), Pedot:Pss, TPD or F4TCNQ.

For example, the hole transport layer may be made of aromatic diamines compounds, triphenylamine compounds, aromatic triamines compounds, biphenyldiamine derivatives, triarylamine polymers, and carbazole polymers. For example, the materials of the hole transport layer may be NPB, TPD, TCTA and polyvinyl carbazole or a monomer thereof.

For example, the electron transport layer may be made of phenanthrola derivatives, oxazole derivatives, thiazole derivatives, imidazole derivatives, metal complexes, and anthracene derivatives. The specific examples include: 8-hydroxyquinoline aluminum (Alq₃), 8-lithium hydroxyquinoline (Liq), 8-hydroxyquinoline gallium, bis [2-(2-hydroxyphenyl-1)-pyridine] beryllium, 2-(4-diphenyl)-5-(4-tert-butylphenyl)-1,3,4-oxadiazole (PBD), 1,3,5-tris (N-phenyl-2-benzimidazole-2) benzene (TPBI), BCP and Bphen etc. . . .

For example, the electron injection layer may be made of alkali metal oxide, alkali metal fluoride and so on. The alkali metal oxide includes lithium oxide (Li₂O), lithium boron oxide (LiBO), potassium silicate (K₂SiO₃), cesium carbonate (Cs₂CO₃) and so on. The alkali metal fluoride includes lithium fluoride (LiF), sodium fluoride (NaF) and so on.

As a positive voltage connection layer of the OLED device, the anode layer has better conductivity, visible light transparency and higher work function value. For example, the anode layer is usually made of an inorganic metal oxide (such as, indium tin oxide (ITO), zinc oxide (ZnO) and so on.) or an organic conductive polymer (such as PEDOT:PSS, PANI and so on) or a metal material with high work function (such as gold, copper, silver, platinum and so on). For example, the anode layer may be ITO film with sheet resistance of 25Ω/□.

As a negative voltage connection layer of the OLED device, the cathode layer has better conductivity and lower work function. The cathode layer is usually made of a low work function metal material, such as lithium, magnesium, calcium, strontium, aluminum, indium and so on, or ally of the metal material with low function value as mentioned above and copper, gold, and silver.

For example, the light emitting layer may emit red light, green light, blue light, yellow light, white light and so on according to different organic light emitting materials used. The present embodiment does not limit the color of the light emitted by the light emitting layer. In addition, as required, the organic light emitting material of the organic light emitting layer provided by the present embodiment includes a fluorescence light emitting material or a phosphorescence light emitting material, at present, a doping system is generally used, that is, a usable light emitting material may be obtained by mixing a dopant material to a host light emitting material. For example, the host light emitting material may be a metal complex material, anthracene derivatives, aromatic diamine compounds, triphenylamine compounds, aromatic triamine compounds, biphenyldiamine derivatives, or triarylamine polymers etc. For example, the host light emitting material may be bias (2-methyl-8-quinolinolato-N1, 08)-(1,1′-biphenyl-4-hydroxy) aluminum (Balq), 9,10-bias-(2-naphthyl) anthracene (ADN), TAZ, 4,4′-bias (9-carbazole) biphenyl (CBP), MCP, 4,4′,4″-tris-9-carbazolyltriphenylamine (TCTA) or N,N-bias (α-naphthyl-phenyl)-4,4-diphenylenediamine (NPB) and so on. For example, the fluorescent light emitting material or the dopant material includes coumarin dyes (coumarin 6, C-545T), quinacridone (DMQA), or 4-(naphthalimide)-2-methyl-6-(4-dimethylamino-styrene)-4H-pyran (DCM) series etc. For example, the phosphorescence light emitting material or the dopant material includes the metal complex light emitting material based on Ir, Pt, Ru, Cu and so on, such as FIrpic, Fir6, FirN4, FIrtaz, Ir(ppy)₃, Ir(ppy)₂(acac), PtOEP, (btp)₂Iracac, Ir(piq)₂(acac) or (MDQ)₂Iracac etc. In addition, the light emitting material may also include a case of dual hosts with dopant.

A material of each layer of the organic light emitting layer is not limited to the cases listed above, and may refer to a usual design. Each layer of the OLED device may satisfy an energy level matching condition.

For example, the plurality of micro organic light emitting diodes include micro organic light emitting diodes emitting light of different colors. Therefore, the micro organic light emitting diodes may achieve full-color display. Taking an evaporation method to form red, green and blue light emitting layer as an example. In a case of evaporating some materials (take red light emitting material as an example), the openings in the mask plate is aligned with red sub-pixels, and green sub-pixels and blue sub-pixels are blocked by the mask plate, so that the red light emitting material evaporated from a crucible may be accurately deposited only on a red sub-pixel region; in a case that the evaporation of the red light emitting material is completed, the mask plate is translated by a distance of one sub-pixel to align the openings with the sub-pixel of another color, and so on to complete the evaporation of RGB three color material, so as to form a color pixel pattern.

FIG. 6 is a view of a micro OLED device emitting light of one color which is formed on a display substrate provided by the present embodiment, in FIG. 6, the organic light emitting layer 213 is manufactured by the mask plate as illustrated in FIG. 1, taking the organic light emitting layer 213 of the red sub-pixel as an example. After forming the light emitting layer of the red sub-pixel, the mask plate is translated by a distance of one sub-pixel to align the openings with the sub-pixel of another color, for example, the green sub-pixel, after forming the light emitting layer of the green sub-pixel, the mask plate is translated by a distance of one sub-pixel to align the openings with the sub-pixel of another color, for example, the blue sub-pixel, therefore, the evaporation of RGB three color material is completed, so as to form a color pixel pattern.

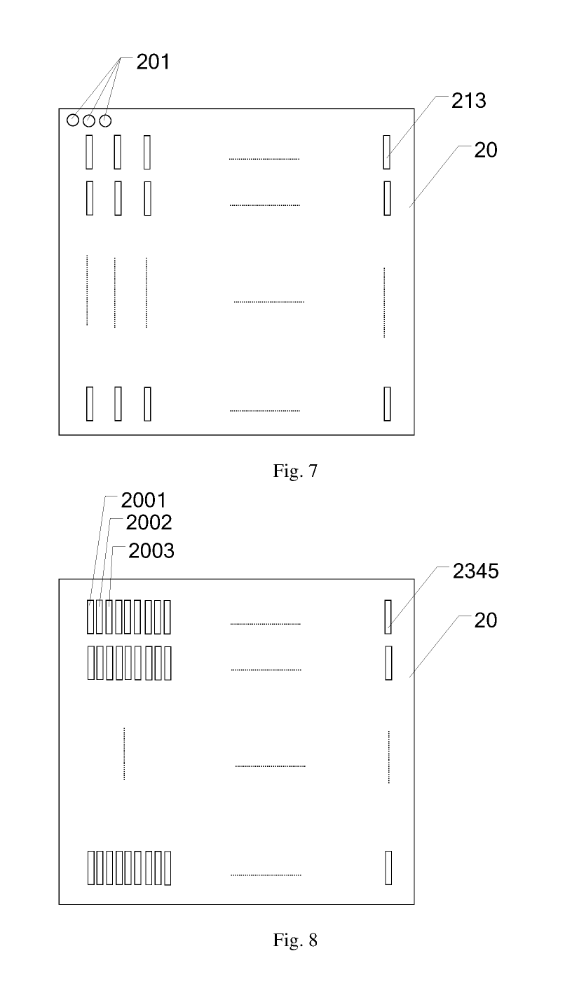

FIG. 7 is a view of a micro OLED device emitting light of one color which is formed on a display substrate provided by the present embodiment, assuming that the mask plate illustrated in FIG. 2 is used for the evaporation, the organic light emitting layer 213 of the formed micro OLED device 2345 of a certain color may be illustrated in FIG. 7.

For example, FIG. 8 is a view of a pixel structure in an OLED display substrate provided by the present disclosure embodiment, a pixel structure of an organic light emitting diode display substrate formed by a method in the present embodiment may be illustrated in FIG. 8. For example, each pixel includes a plurality of sub-pixels. FIG. 8 illustrates a first color sub-pixel 2001, a second color sub-pixel 2002 and a third color sub-pixel 2003. For example, the first color sub-pixel 2001 is a red sub-pixel, the second color sub-pixel 2002 is a green sub-pixel, and the third color sub-pixel 2003 is a blue sub-pixel. For example, one pixel may include the red sub-pixel, the green sub-pixel and the blue sub-pixel, but not limited thereto, one pixel may further include sub-pixels of other colors. For example, in FIG. 8, the color of each column sub-pixel is the same. For example, each sub-pixel is corresponding to a micro OLED device.

For example, an area of each of the micro organic light emitting diodes is greater than or equal to 1 square micron and less than or equal to 300 square microns. Any mask plate provided by the present embodiment may be used for manufacturing the micro organic light emitting diode. For example, the area of each of the micro organic light emitting diodes is greater than or equal to 1 square micron and less than or equal to 150 square microns. For example, the area of each of the micro organic light emitting diodes is greater than or equal to 10 square microns and less than or equal to 110 square microns. It should be noted that, the arrangement of the sub-pixels is not limited to a case illustrated in FIG. 8.

The above is described by taking the formation of the organic light emitting layer 213 as an example, a manufacturing method of other layers of the micro OLED device 2345 may refer to the manufacturing method of the organic light emitting layer 213.

The present embodiment is described by taking an example of silicon-based AMOLED display substrate with the structure illustrated in FIG. 4 as an example. However, a structure of the OLED display substrate formed by the present embodiment is not limited to a case illustrated in FIG. 4.

The arrangement of the plurality of openings in the mask plate may be manufactured according to the sub-pixels to be manufactured, but is not limited to the case provided by the present embodiment. The rectangular openings are taken as an example in the drawings, but an embodiment of the present disclosure is not limited to the shape of the openings. An embodiment of the present disclosure is not limited to the shape of the sub-pixels.

In an embodiment of the present disclosure, the mask plate for manufacturing the micro organic light emitting diode display is described as an example, but is not limited thereto, the mask plate provided by the present disclosure may also be used to manufacture non-micro OLED device. The openings with corresponding size may be formed according to the pixel structure to be manufactured. And the pixel structure is not limited to a case listed in an embodiment of the present disclosure, but other pixel structures may also be used, such as the pixel structure that adjacent two rows of sub-pixels are offset by a half sub-pixel distance.

The following points should to be explained:

1) Unless otherwise defined, the same reference numerals in at least one embodiment and the drawings of the present disclosure represent the same meaning.

2) The drawings of at least one embodiment of the present disclosure only relate to the structure in the embodiment of the present disclosure, and other structures may be referenced to the usual design.

3) For clarity purposes, the thickness and size of a layer or microstructure are amplified in the drawings for at least one embodiment of the present disclosure. It should be understood that, in a case that a component such as a layer, a membrane, a region, or a substrate is referred to be located “on” or “down” another element, the component may be located “on” or “down” the another element “directly”, or may have an intermediate element.

The above are only specific implementations of the present disclosure, and the scope of the present disclosure is not limited thereto, the scope of the present disclosure should be based on the scope of the claims.

The present application claims priority to the Chinese patent application No. 201610994601.8 filed Nov. 11, 2016, the entire disclosure of which is incorporated herein by reference as part of the present application.

1. A mask plate, comprising a mask substrate and a plurality of openings passing through the mask substrate, wherein a material of the mask plate is monocrystalline silicon.

2. The mask plate according to claim 1, wherein the mask substrate has a thickness of 100 microns to 300 microns.

3. The mask plate according to claim 1, wherein the plurality of openings are arranged in a matrix, the matrix comprises a plurality of rows and a plurality of columns, at least one of lengths in a row direction and in a column direction of each of the openings is less than or equal to 10 microns.

4. The mask plate according to claim 1, wherein the plurality of openings extend in a first direction, and are arranged in a second direction which is perpendicular to the first direction, a length of each of the openings in the second direction is less than or equal to 10 microns.

5. The mask plate according to claim 1, further comprising an alignment hole, wherein the alignment hole is disposed in the mask substrate, and configured to be aligned with an alignment mark of a display substrate.

6. The mask plate according to claim 1, wherein the mask plate is configured to form at least one layer of a micro organic light emitting diode, an area of the micro organic light emitting diode is greater than or equal to 1 square micron and less than or equal to 300 square microns.

7. A manufacturing method of a mask plate, comprising:
forming a plurality of openings in a mask substrate with the opening passing through the mask substrate;
wherein a material of the mask plate is monocrystalline silicon.

8. The manufacturing method of the mask plate according to claim 7, wherein before forming the plurality of openings, the manufacturing method further comprises thinning a mask material to form the mask substrate, the mask substrate has a thickness of 100 microns to 300 microns.

9. A manufacturing method of an organic light emitting diode display, comprising forming a plurality of micro organic light emitting diodes, at least one layer of the micro organic light emitting diodes is formed by using the mask plate according to claim 1.

10. The manufacturing method of the organic light emitting diode display according to claim 9, wherein an area of each of the micro organic light emitting diodes is greater than or equal to 1 square micron and less than or equal to 300 square microns.

11. The manufacturing method of the organic light emitting diode display according to claim 9, wherein the at least one layer of the micro organic light emitting diodes comprises at least one of a hole injection layer, a hole transport layer, a hole blocking layer, a light emitting layer, an electron injection layer, an electron transport layer, an electron blocking layer and an electrode layer.

12. The manufacturing method of the organic light emitting diode display according to claim 9, wherein the plurality of micro organic light emitting diodes comprise micro organic light emitting diodes emitting light of different colors.

13. The mask plate according to claim 2, wherein the plurality of openings are arranged in a matrix, the matrix comprises a plurality of rows and a plurality of columns, at least one of lengths in a row direction and in a column direction of each of the openings is less than or equal to 10 microns.

14. The mask plate according to claim 2, wherein the plurality of openings extend in a first direction, and are arranged in a second direction which is perpendicular to the first direction, a length of each of the openings in the second direction is less than or equal to 10 microns.

15. The mask plate according to claim 2, further comprising an alignment hole, wherein the alignment hole is disposed in the mask substrate, and configured to be aligned with an alignment mark of a display substrate.

16. The mask plate according to claim 2, wherein the mask plate is configured to form at least one layer of a micro organic light emitting diode, an area of the micro organic light emitting diode is greater than or equal to 1 square micron and less than or equal to 300 square microns.

17. The manufacturing method of the organic light emitting diode display according to claim 10, wherein the at least one layer of the micro organic light emitting diodes comprises at least one of a hole injection layer, a hole transport layer, a hole blocking layer, a light emitting layer, an electron injection layer, an electron transport layer, an electron blocking layer and an electrode layer.

18. The manufacturing method of the organic light emitting diode display according to claim 10, wherein the plurality of micro organic light emitting diodes comprise micro organic light emitting diodes emitting light of different colors.
